(19) United States
(12) Patent Application Publication
(10) Pub. No.: US 2026/0349570 A1
(43) Pub. Date: Nov. 5, 2026

(54) Display Device

(71) Applicant: LG Display Co., Ltd., Seoul (KR)

(72) Inventors: JaeGyun Lee, Seoul (KR); JiHyun Jung, Seoul (KR); Ruda Rhe, Seoul (KR); Hyangmyoung Gwon, Seoul (KR)

(21) Appl. No.: 19/633,132

(22) Filed: Mar. 30, 2026

(30) Foreign Application Priority Data
Apr. 30, 2025 (KR) 10-2025-0057449

(51) Int. Cl. G06F 3/044; G06F 3/041; H10H 29/45; H10H 29/49; H10H 29/80; H10H 29/85; H10H 29/855

(52) U.S. Cl. CPC G06F 3/0446; G06F 3/04164; G06F 3/0445; H10H 29/45; H10H 29/49; H10H 29/842; H10H 29/8517; H10H 29/8552; G06F 2203/04111

(57) ABSTRACT

A display device presented herein includes a first substrate including a first display area and a first non-display area outside the first display area, a second substrate on the first substrate and including a second display area and a second non-display area, a plurality of first pads disposed in the first non-display area, a plurality of touch electrodes disposed in the second display area below the second substrate, a plurality of bridge electrodes disposed in the second display area below the second substrate, and a plurality of second pads disposed in the second non-display area below the second substrate. The plurality of first pads is disposed on one side portion of the first substrate, and the plurality of second pads is disposed on the other side portion of the second substrate that does not overlap with one side portion of the first substrate.

### CROSS-REFERENCE TO RELATED APPLICATION

This application claims priority to Republic of Korea Patent Application No. 10-2025-0057449, filed on Apr. 30, 2025, which is incorporated herein by reference in its entirety.

### TECHNICAL FIELD

The present disclosure relates to a display device, and more particularly, to a display device including a touch sensing unit.

### BACKGROUND

In the field of display devices that visually display electrical information signals, research is being conducted to develop performances such as thinning, weight reduction, and low power consumption for various display devices. Representative display devices include a liquid crystal display (LCD), a field emission display (FED), an electro-wetting display (EWD), and an organic light emitting display (OLED).

In order to provide more various functions to the user, a display device that recognizes a user's touch on a display panel and provides a touch function that performs input processing based on the recognized touch has been developed. The display device capable of touch recognition includes a plurality of touch electrodes disposed on or embedded in the display panel, and may detect the presence or absence of a user's touch on the display panel and touch coordinates by driving the touch electrodes. In this way, in the case of a display device capable of touch recognition, an encapsulation substrate provided with a touch sensing unit may be disposed on the display panel to prevent moisture permeation or oxygen inflow into the display panel. When the display panel and the encapsulation substrate are bonded, there is a need for a method of efficiently disposing a touch pad while preventing damage to a touch pad to which a signal for operation of the touch sensing unit is applied.

### SUMMARY

An object to be achieved by the present disclosure is to provide a display device in which a flexible film is efficiently attached to a touch pad disposed on an encapsulation substrate without damage in a structure in which a display substrate and an encapsulation substrate are bonded.

Another object to be achieved by the present disclosure is to provide a display device capable of efficiently reducing a resistance of a touch pad and a touch routing line disposed on an encapsulation substrate.

Still another object to be achieved by the present disclosure is to provide a display device which easily checks a touch pad attached from a lower portion of an encapsulation substrate, an alignment mark of a flexible film, and an indentation of an adhesive layer.

Objects of the present disclosure are not limited to the above-mentioned objects, and other objects, which are not mentioned above, can be clearly understood by those skilled in the art from the following descriptions.

According to one or more embodiments of the present disclosure, a display device comprises a first substrate including a first display area in which a plurality of sub pixels are disposed and a first non-display area outside the first display area, a second substrate which is opposite to the first substrate on an upper portion of the first substrate and includes a second display area corresponding to the first display area and a second non-display area outside the second display area, a plurality of first pads disposed in the first non-display area of the first substrate, a plurality of touch electrodes disposed in the second display area under the second substrate, a plurality of bridge electrodes disposed in the second display area under the second substrate, disposed on a different layer from the plurality of touch electrodes, and electrically connected to some of the plurality of touch electrodes and a plurality of second pads disposed in the second non-display area under the second substrate and electrically connected to each of the plurality of touch electrodes, the plurality of first pads are disposed on one side portion of the first substrate and the plurality of second pads are disposed on the other side portion of the second substrate that does not overlap with one side portion of the first substrate.

A display device according to one or more other embodiments of the present disclosure includes a first substrate including a display area in which a plurality of light emitting elements are disposed, and a non-display area outside the display area; a second substrate which is opposite to the first substrate from an upper portion of the first substrate; a filling layer disposed between the first substrate and the second substrate; at least one dam which is disposed between the first substrate and the second substrate to surround an outer surface of the filling layer to confine the filling layer; a plurality of first touch electrodes which are disposed in a first area corresponding to the display area under the second substrate and extends in a first direction; a plurality of second touch electrodes which extend in a second direction intersecting the first direction; a plurality of bridge electrodes which are disposed in the first area under the second substrate and are disposed on a different layer from the plurality of first touch electrodes and the plurality of second touch electrodes and are electrically connected to a portion of the plurality of second touch electrodes; a plurality of touch routing lines which extend from the first area and is disposed in the second area at least partially overlapping the non-display area; a plurality of touch pads which extends from the second area and is disposed in the third area non-overlapping with non-display area at one side of the second substrate; and a second flexible film which is electrically connected to the plurality of touch pads at a lower portion of the second substrate.

Other detailed matters of the embodiments are included in the detailed description and the drawings.

A display device according to one or more embodiments of the present disclosure includes side portions in which a display substrate and an encapsulation substrate facing each other are non-overlapping, a signal pad and a first flexible film are attached in a non-display area of the non-overlapping side portion of the display substrate, and a touch pad and a second flexible film may be attached in a non-display area of the non-overlapping side portion of the encapsulation substrate, so that even in a state in which the display substrate and the encapsulation substrate facing each other are bonded, an easy attachment is possible without damage to each of the signal pad and the touch pad and the flexible film.

In the display device according to one or more embodiments of the present disclosure, a touch sensing unit is provided on the encapsulation substrate, and the touch pad and the touch routing line are implemented using the touch electrode and the bridge electrode of the touch sensing unit to reduce the resistance of each of the touch pad and the touch routing line, and the touch pad and the flexible film are easily attached under the encapsulation substrate.

In the display device according to one or more embodiments of the present disclosure, a color filter and a black matrix are provided on the encapsulation substrate, and the black matrix is disposed on one side of the encapsulation substrate from the outermost portion of the encapsulation substrate to a position spaced inward from the outermost portion of the encapsulation substrate, so that when the touch pad and the flexible film are attached to the lower portion of the encapsulation substrate, an alignment mark for alignment between the touch pad and the flexible film may be easily checked, and the indentation of the adhesive layer electrically bonding the touch pad and the flexible film may also be easily checked.

The effects according to the present disclosure are not limited to the contents exemplified above, and more various effects are included in the present disclosure.

### BRIEF DESCRIPTION OF THE DRAWINGS

The above and other embodiments, features and other advantages of the present disclosure will be more clearly understood from the following detailed description taken in conjunction with the accompanying drawings, in which:

FIG. 1 is a schematic exploded perspective view of a display device according to one or more embodiments of the present disclosure.

FIG. 2 is a plan view of a display device as seen from an upper portion of an encapsulation substrate according to one or more embodiments of the present disclosure.

FIG. 3 is a plan view of a display device as viewed from a lower portion of an encapsulation substrate according to one or more embodiments of the present disclosure.

FIG. 4 is an example of a cross-sectional view taken along line I-I' in FIG. 2.

FIG. 5 is another example of a cross-sectional view taken along line I-I' in FIG. 2.

FIG. 6 is an example of a cross-sectional view taken along line II-II' of FIG. 2.

FIG. 7 is another example of a cross-sectional view taken along line II-II' of FIG. 2.

FIG. 8 is an example of a cross-sectional view taken along line III-III' of FIG. 3.

FIG. 9 is another example of a cross-sectional view taken along line III-III' of FIG. 3.

FIG. 10 is an example of a cross-sectional view taken along line IV-IV' of FIG. 3.

FIG. 11 is another example of a cross-sectional view taken along line IV-IV' of FIG. 3.

### DETAILED DESCRIPTION

Advantages and characteristics of the present disclosure and a method of achieving the advantages and characteristics will be clear by referring to embodiments described below in detail together with the accompanying drawings. However, the present disclosure is not limited to the embodiments disclosed herein but will be implemented in various forms. The embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the embodiments of the present disclosure are merely examples, and the present disclosure is not limited thereto. Further, in the following description of the present disclosure, a detailed explanation of known related technologies may be omitted to avoid unnecessarily obscuring the subject matter of the present disclosure. The terms such as “including,” “having,” “comprising,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, embodiments of the present disclosure will be described with reference to the drawings.

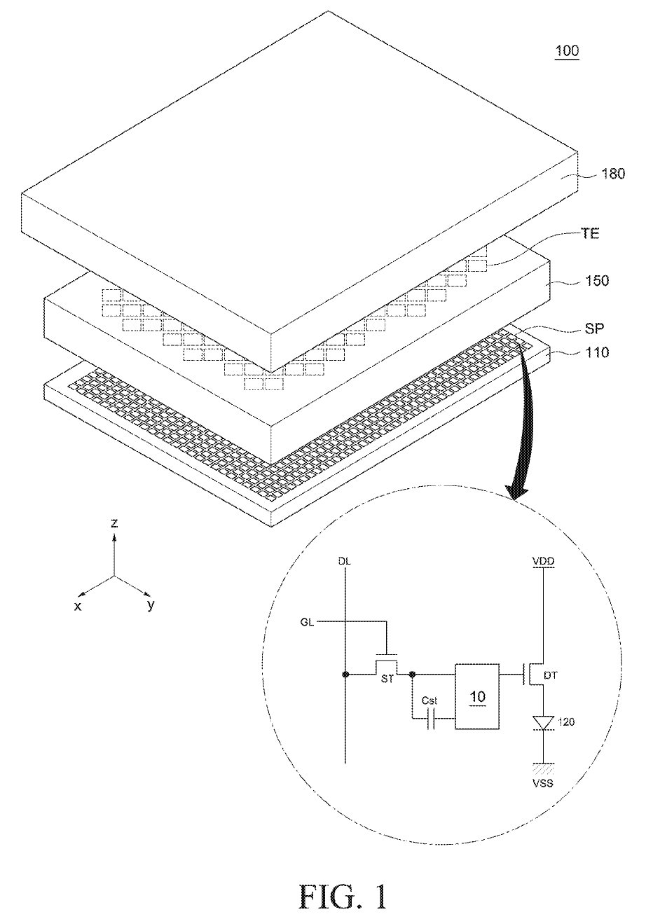

FIG. 1 is a schematic exploded perspective view of a display device according to one or more embodiments of the present disclosure.

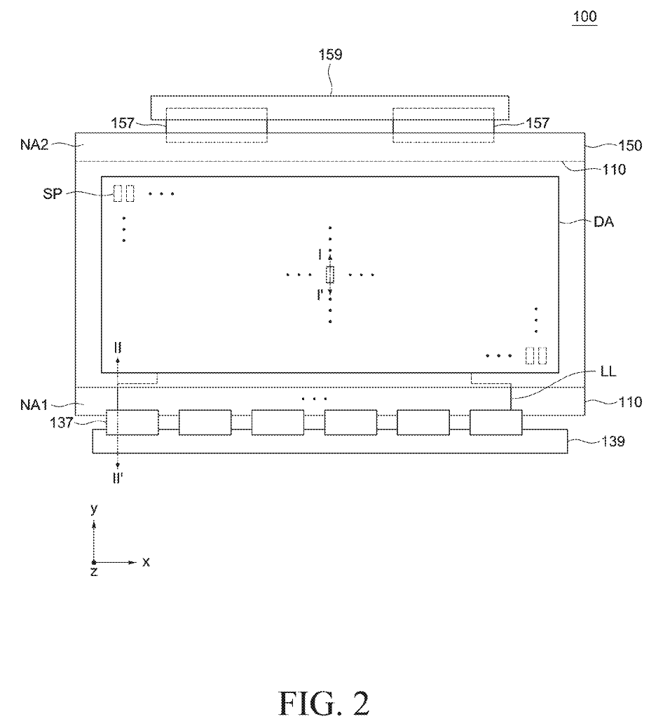

FIG. 2 is a plan view of a display device as seen from an upper portion of an encapsulation substrate according to one or more embodiments of the present disclosure.

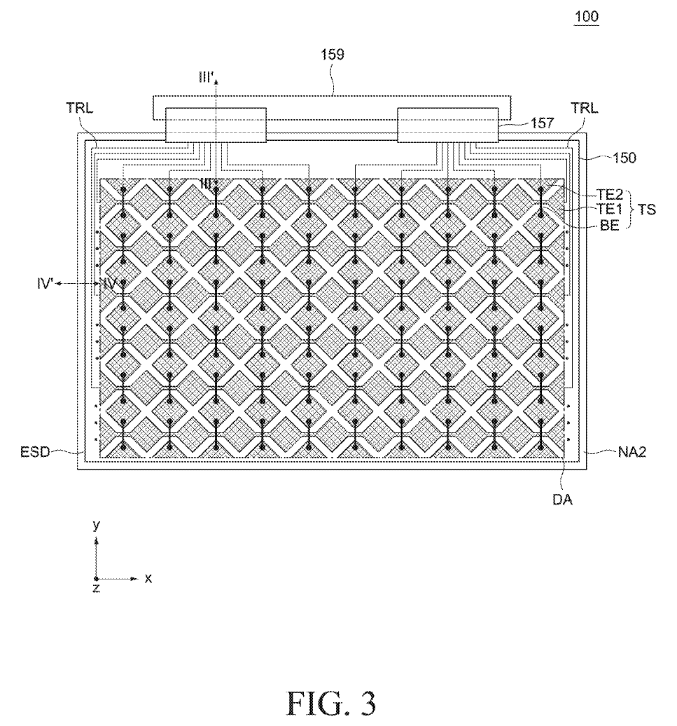

FIG. 3 is a plan view of a display device as viewed from a lower portion of an encapsulation substrate according to one or more embodiments of the present disclosure.

Referring to FIGS. 1 to 3 together, a display device 100 according to one or more embodiments of the present disclosure includes a first substrate 110, a second substrate 150 having one surface opposite to the first substrate 110, and a third substrate 180 having one surface opposite to the other surface of the second substrate 150. A plurality of sub pixels SP are arranged on one surface of the first substrate 110 facing the second substrate 150. The plurality of touch electrodes TE are disposed on one surface of the second substrate 150 facing the first substrate 110. In one or more embodiments of the present disclosure, it is described that the second substrate 150 is disposed on the first substrate 110 and the third substrate 180 is disposed on the second substrate 150. For example, the first substrate 110, the second substrate 150, and the third substrate 180 may be sequentially disposed with respect to the z-axis shown in FIG. 1. In one or more embodiments of the present disclosure, the third substrate 180 may be referred to as a cover member 180.

The first substrate 110 is a component for supporting various components included in the display device 100 and may be made of a transparent insulating material, for example, glass or resin. In addition, the first substrate 110 may include polymer or plastic, or may be made of a material having flexibility. In one or more embodiments of the present disclosure, the first substrate 110 may be referred to as a “display substrate”.

The first substrate 110 includes a display area DA (hereinafter referred to as a “first display area”) in which a plurality of sub pixels SP implementing an image is disposed, and a non-display area NA1 (hereinafter referred to as a “first non-display area”) outside the first display area DA. The first non-display area NA1 of the first substrate 110 may be an area in which the plurality of sub pixels SP is not disposed, that is, an area in which no image is displayed, and may be an area extending from the first display area DA.

A plurality of gate lines GL and a plurality of data lines DL are disposed to cross each other on the first substrate 110, and a plurality of sub pixels SP are defined at intersection points between the plurality of gate lines GL and the data line DL. In the first display area DA of the first substrate 110, a plurality of sub pixels SP constituting each of the plurality of pixels, and a pixel driving circuit for driving the plurality of sub pixels SP may be disposed. For example, the pixel driving circuit may include a driving transistor DT, a switching transistor ST, and a capacitor Cst. The driving transistor DT may operate such that a driving current flows between a high potential power line VDD and a low potential power line VSS according to a data voltage stored in the capacitor Cst. The light emitting element 120 may operate to emit light according to a driving current formed by the driving transistor DT. The switching transistor ST may perform a switching operation such that a data signal supplied through the data line DL is stored in the capacitor Cst as a data voltage in response to a gate signal supplied through the gate line GL. In the above, it has been described as an example that the pixel driving circuit of each sub pixel SP is configured in a 2T(transistor)1C(capacitor) structure including one driving transistor, one switching transistor, and one capacitor. As another example, the sub pixel SP may further include a compensation circuit 10. The compensation circuit 10 is a circuit for compensating for a threshold voltage of a driving transistor. For example, when the compensation circuit is added to the pixel driving circuit, the compensation circuit may have various structures such as 3T1C, 4T2C, 5T2C, 6T1C, 6T2C, 7T1C, 7T2C, etc.

A display device 100 according to one or more embodiments of the present disclosure may include an image processing unit which outputs a data signal supplied from the outside and a driving signal including at least one of a data enable signal, a vertical synchronization signal, a horizontal synchronization signal, and a clock signal. The display device 100 may further include a timing controller which receives the driving signal and the data signal from the image processing unit and outputs a gate timing control signal for controlling an operation timing of a gate driver and a data timing control signal for controlling the data signal and the operation timing of the data driver based on the driving signal. The display device 100 may further include a data driver which processes the data signal supplied from the timing controller in response to the data timing control signal supplied from the timing controller and outputs the data signal through a plurality of data lines DL. The display device 100 may further include a gate driver which outputs the gate signal through the gate lines GL while outputting the gate signal in response to the timing control signal.

In the first non-display area NA1 of the first substrate 110, a signal link line LL and a plurality of signal pads which are electrically connected to a plurality of sub pixels SP disposed in the first display area DA and transmit various signals and power for driving the sub pixels SP and driving circuits such as a gate driver and a data driver which are electrically connected to the signal pads may be disposed. In this case, driving units and driving circuits, such as a gate driver and a data driver, may be implemented by one or more integrated circuits (IC) and may be implemented by a chip on glass (COG) type, a chip on film (COF) type, or a tape carrier package (TCP) type. Further, in the first non-display area NA1 of the first substrate 110, a gate driving circuit included in the gate driver may be disposed in a gate in panel (GIP). The display device 100 according to one or more embodiments of the present disclosure may include a COF-type flexible film 137 on which a driving integrated circuit such as a gate driver and a data driver is mounted. Further, the display device 100 may include a circuit board 139 on which a plurality of circuits implemented by a plurality of driving chips, such as a timing controller, are mounted. The circuit board 139 may be a printed circuit board (PCB) or a flexible printed circuit board (FPCB), and may be attached to be electrically connected to the flexible film 137.

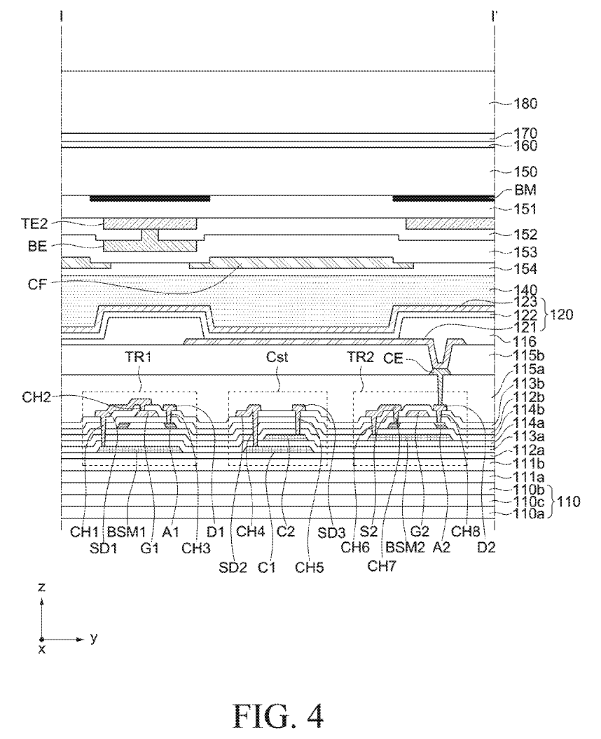

Meanwhile, because the light emitting element 120 for each of the plurality of sub pixels SP disposed in the first display area DA of the first substrate 110 is vulnerable to external moisture or oxygen, etc., a filling layer (shown as “140” in FIGS. 4 to 11 below) and at least one dam (shown as “145” in FIGS. 4 to 11 below) are disposed on the first substrate 110, and the second substrate 150 is disposed to cover the filling layer 140 and the dam 145, thereby sealing the plurality of light emitting elements 120 on the first substrate 110. For example, the second substrate 150 may be made of a transparent insulating material, for example, glass or resin. In one or more embodiments of the present disclosure, the second substrate 150 may be referred to as a “sealing substrate”.

Referring to FIG. 3, a touch sensing unit TS including a plurality of touch electrodes TE1 and TE2 and a plurality of bridge electrodes BE is disposed on one surface of the second substrate 150. In this case, the touch sensing unit TS is disposed in a display area (hereinafter, referred to as a “second display area”) corresponding to the first display area DA of the first substrate 110 on a lower surface of the second substrate 150 (i.e., a surface of the second substrate 150 facing the first substrate 110). The touch sensing unit TS includes a plurality of first touch electrodes TE1 extending in a first direction (i.e., the x-axis direction of FIG. 3) and a plurality of second touch electrodes TE2 extending in a second direction (i.e., the y-axis direction of FIG. 3) which intersects the first direction and disposed on the same layer as the plurality of first touch electrodes TE1. Each of the plurality of first touch electrodes TE1 and the plurality of second touch electrodes TE2 may include a plurality of unit electrodes. For example, each of the first touch electrode TE1 and the second touch electrode TE2 may include a plurality of unit electrodes patterned in a mesh shape. FIG. 3 illustrates that the unit electrodes in which the first touch electrode TE1 and the second touch electrode TE2 are formed in a rhombic mesh pattern are continuous shapes. However, the present disclosure is not limited thereto. The unit electrodes may have various shapes, such as a triangle, a square, a rhombic, or a polygon. In this case, the mesh patterns of the unit electrodes of the first touch electrode TE1 and the second touch electrode TE2 may be implemented by touch electrode lines surrounding openings corresponding to the emission area of the sub pixel SP, respectively. This touch electrode line is a part corresponding to a substantial touch electrode, and is a part to which a touch driving signal is applied or a touch sensing signal is sensed. Further, the touch sensing unit TS includes a bridge electrode which electrically connects unit electrodes of each of the first touch electrode TE1 and the second touch electrode TE2. Referring to FIG. 3, the bridge electrode connecting the unit electrodes of the first touch electrode TE1 is disposed on the same layer as the first touch electrode TE1, and the bridge electrode BE connecting the unit electrodes of the second touch electrode TE2 may be disposed on a different layer from the second touch electrode TE2. In this case, the bridge electrode connecting the unit electrodes of the first touch electrode TE1 may be integrally implemented by extending from the unit electrode of the first touch electrode TE1. The plurality of first touch electrodes TE1, the plurality of second touch electrodes TE2, and the plurality of bridge electrodes BE may each be formed of a metal including at least any one of titanium (Ti), aluminum (Al), molybdenum (Mo), molybdenum-titanium (MoTi), copper (Cu), and tantalum (Ta), and may be formed of a transparent conductive material such as indium tin oxide (ITO), indium zinc oxide (IZO), or the like, but are not limited thereto.

Light emitted from the display device 100 may pass through the plurality of first touch electrodes TE1 and the plurality of second touch electrodes TE2 made of a transparent conductive material and be emitted to the outside. The present disclosure is not limited thereto, and light emitted from the display device 100 may be emitted to the outside through a plurality of openings included in the plurality of first touch electrodes TE1 and the plurality of second touch electrodes TE2.

The display device 100 according to one or more embodiments of the present disclosure may sense a touch by a mutual-capacitance-based touch sensing method, which is a capacitance-based touch sensing method. For example, the plurality of first touch electrodes TE1 may be touch driving electrodes and the plurality of second touch electrodes TE2 may be touch sensing electrodes. However, the present disclosure is not limited thereto. The plurality of first touch electrodes TE1 may be touch sensing electrodes and the plurality of second touch electrodes TE2 may be touch driving electrodes. Further, the display device 100 according to one or more embodiments of the present disclosure may sense a touch by a self-capacitance-based touch sensing method.

The second substrate 150 includes a non-display area NA2 (hereinafter, referred to as a “second non-display area”) that is an area outside the second display area, and the second non-display area NA2 is an area in which the touch sensing unit TS is not disposed and may be an area extending from the second display area. A plurality of touch routing lines TRL electrically connected to the plurality of first touch electrodes TE1 and the plurality of second touch electrodes TE2 respectively, a plurality of touch pads electrically connected to the plurality of touch routing lines TRL, respectively, and a touch driving circuit electrically connected to the touch pads may be disposed in the second non-display area NA2 below the second substrate 150. For example, the plurality of touch routing lines TRL may be formed of a low-resistance metal material, or may be formed of a transparent conductive material such as ITO or IZO. For example, when the plurality of touch routing lines TRL is made of a low-resistance metal material, the resistance is lowered and the RC delay may be lowered.

In order to provide a touch sensing function, the display device 100 according to one or more embodiments of the present disclosure may include a touch sensing circuit that supplies a touch driving signal to the touch sensing unit TS and detects a touch sensing signal from the touch sensing unit TS to sense the presence or absence of a user's touch and a touch position (or coordinate). For example, the touch sensing circuit may include a touch driving circuit which supplies a touch driving signal to the touch sensing unit TS and detects a touch sensing signal by a user's touch from the touch sensing unit TS and a touch controller which senses the presence or absence of a user's touch and/or the touch position based on the touch sensing signal detected by the touch driving circuit. The touch driving circuit and the touch controller may be implemented as separate components or integrated into one component in some cases. The display device 100 according to one or more embodiments of the present disclosure may include a COF type flexible film 157 on which an integrated circuit such as a touch driving circuit is mounted. Further, the display device 100 according to one or more embodiments of the present disclosure may include a circuit board 159 on which a plurality of circuits implemented by a plurality of driving chips, such as a touch controller, are mounted. The circuit board 159 may be a printed circuit board (PCB) or a flexible printed circuit board (FPCB) and may be attached to be electrically connected to the flexible film 157.

Meanwhile, as illustrated in FIG. 3, an electrostatic discharge circuit ESD which discharges static electricity entering from the outside may be disposed in the second non-display area NA2 of the second substrate 150. For example, the electrostatic discharge circuit ESD may be disposed between the outermost touch routing line TRL, among the plurality of touch routing lines TRL, and the outermost portion of the second substrate 150. Further, the electrostatic discharge circuit ESD is disposed to surround the second display area of the second substrate 150 and may be connected to a ground terminal of an integrated circuit in which an end portion is mounted on the flexible film 157. For example, the electrostatic discharge circuit ESD may be implemented by one or more transistors, and the transistor constituting the electrostatic discharge circuit ESD may include electrodes which are disposed on the same layer and made of the same material as the touch electrodes TE1 and TE2 and the bridge electrode BE, respectively.

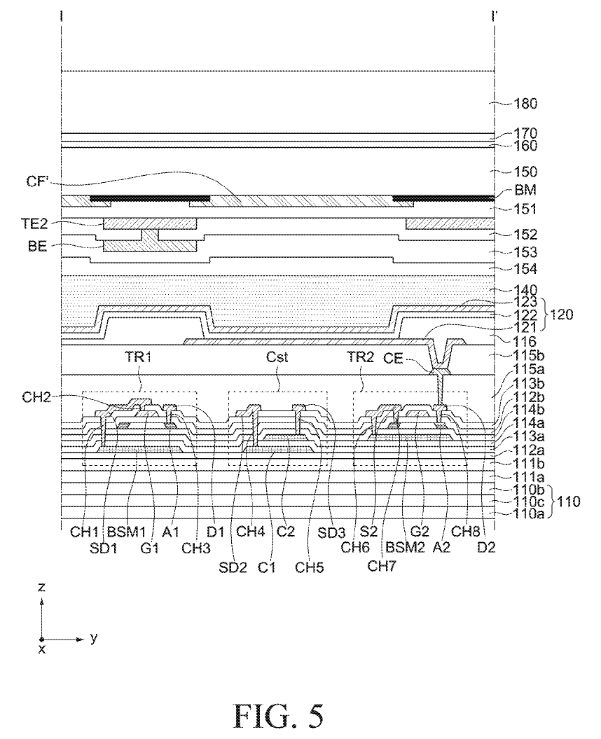

Hereinafter, a structure of the display area DA of the display device 100 according to one or more embodiments of the present disclosure will be described in detail with reference to FIGS. 4 and 5. The structure of the display area DA illustrated in FIG. 5 is substantially the same as the structure of the display area DA illustrated in FIG. 4 except for an arrangement position of a plurality of color filters CF', so that a redundant description will be omitted.

FIG. 4 is an example of a cross-sectional view taken along line I-I' in FIG. 2.

FIG. 5 is another example of a cross-sectional view taken along line I-I' in FIG. 2.

Referring to FIG. 4, the first substrate 110 may include a substrate 110a, a substrate 110b, and an interlayer insulating film 110c. The interlayer insulating film 110c may be disposed between the substrate 110a and the substrate 110b. For example, the substrate 110aand the substrate 110b may be polyimide (PI) substrates, and the interlayer insulating film 110c may be formed of a single film of silicon nitride SiNx) or silicon oxide (SiOx) or multiple films thereof. As described above, the first substrate 110 is configured by the substrate 110a, the substrate 110b, and the interlayer insulating film 110c, thereby effectively preventing moisture permeation.

The first multi-buffer layer 111a may be disposed on the first substrate 110, and the first active buffer layer 111b may be disposed on the first multi-buffer layer 111a. The first multi-buffer layer 111a and the first active buffer layer 111b may delay diffusion of moisture or oxygen introduced into the first substrate 110, and for example, may include at least one of silicon nitride (SiNx) and silicon oxide (SiOx).

The first insulating layer 112a is disposed on the first active buffer layer 111b. For example, the first insulating layer 112amay be configured by a single layer of silicon nitride (SiNx) or silicon oxide (SiOx) or a multi-layer thereof.

The first blocking layer BSM1 and the first capacitor electrode C1 of the capacitor Cst are disposed on the first insulating layer 112a. The first blocking layer BSM1 may be a metal film serving as a light shield in order to suppress a problem in which light incident from the outside of the display device is irradiated to the semiconductor layer and the semiconductor layer is deteriorated. For example, the blocking layer may have an area larger than an area of the active layer of the thin film transistor, but is not limited thereto. In addition, the blocking layer may prevent a problem in which electric charges are introduced from the first substrate 110. FIG. 4 illustrates that the first blocking layer BSM1 is disposed on the first insulating layer 112a. However, the position of the first blocking layer BSM1 is not limited thereto. For example, the first blocking layer BSM1 is a metal film disposed relatively below the stacked structure of the sub pixel. The first blocking layer BSM1 may be disposed between the first active buffer layer 111b and the first insulating layer 112a, between the first multi-buffer layer 111a and the first active buffer layer 111b, or between the first multi-buffer layer 111a and the first substrate 110.

The first capacitor electrode C1 may be disposed on the same layer as the first blocking layer BSM1 and may be formed of the same material. For example, the first capacitor electrode C1 may be formed of a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof.

The first interlayer insulating layer 113a is disposed on the first insulating layer 112a while covering the first blocking layer BSM1 and the first capacitor electrode C1. For example, the first interlayer insulating layer 113a may be configured by a single layer of silicon nitride (SiNx) or silicon oxide (SiOx) or a multi-layer thereof.

The second capacitor electrode C2 of the capacitor Cst is disposed on the first interlayer insulating layer 113a. The second capacitor electrode C2 may be disposed to overlap the first capacitor electrode C1. Further, the second capacitor electrode C2 may be formed of the same material as the first capacitor electrode C1. In addition, the second capacitor electrode C2 may be formed of a single layer or a multi-layer formed of any one of molybdenum (Mo), copper (Cu), titanium (Ti), aluminum (Al), chromium (Cr), gold (Au), nickel (Ni), and neodymium (Nd) or an alloy thereof.

In this way, the first capacitor electrode C1 and the second capacitor electrode C2 are disposed on the first insulating layer 112a to overlap each other to implement the capacitor Cst. The capacitor Cst includes two corresponding electrodes and a dielectric disposed therebetween, and for example, a first interlayer insulating layer 113a may be served as the dielectric between the first capacitor electrode C1 and the second capacitor electrode C2.

The second multi-buffer layer 114a is disposed on the first interlayer insulating layer 113a, and the second active buffer layer 114b is disposed on the second multi-buffer layer 114a. Further, a second blocking layer BSM2 is disposed between the second multi-buffer layer 114a and the second active buffer layer 114b.

The second multi-buffer layer 114a may be formed of the same material as the first multi-buffer layer 111a, but is not limited thereto. The second active buffer layer 114bmay be formed of the same material as the first active buffer layer 111b, but is not limited thereto. The second blocking layer BSM2 serves substantially the same role as the first blocking layer BSM1 and may be formed of the same material, but is not limited thereto.

The first transistor TR1 and the second transistor TR2 are disposed on the second active buffer layer 114b. For example, the first transistor TR1 may be a switching transistor and the second transistor TR2 may be a driving transistor, but is not limited thereto. The first transistor TR1 may be a driving transistor and the second transistor TR2 may be designed as a switching transistor based on the structure and driving characteristics of the display device 100 and the structure and type of the thin film transistor.

The first transistor TR1 includes a first active layer A1, a first gate electrode G1, a first source electrode, and a first drain electrode D1. Further, the second transistor TR2 includes a second active layer A2, a second gate electrode G2, a second source electrode S2, and a second drain electrode D2.

Each of the first thin film transistor TR1 and the second thin film transistor TR2 of the display device 100 according to one or more embodiments of the present disclosure may use an oxide semiconductor as an active layer. For example, all transistors constituting the pixel driving circuit included in each of the plurality of sub pixels of the display device 100 may implement an active layer using an oxide semiconductor. A transistor using an oxide semiconductor as an active layer has an excellent leakage current blocking effect, and a manufacturing cost is relatively low compared to a transistor using polycrystalline silicon as an active layer. Accordingly, the power consumption may be reduced and the manufacturing cost may be lowered. However, the present disclosure is not limited thereto, and transistors of only some sub pixels of the display device 100 may implement an active layer using an oxide semiconductor. For example, at least a portion of the pixel driving circuits of the display device 100 may include, as a driving transistor or a switching transistor, a transistor in which an active layer is implemented using polycrystalline silicon, which is relatively easier to secure reliability, relatively faster in operation speed, and may be highly reliable than a transistor using an oxide semiconductor.

The first active layer A1 of the first thin film transistor TR1 and the second active layer A2 of the second thin film transistor TR2 may be disposed to be spaced apart from each other on the second active buffer layer 114b. For example, each of the first active layer A1 and the second active layer A2 may be made of various metal oxides such as indium-gallium-zinc-oxide (IGZO), indium-zinc-oxide (IZO), indium-gallium-tin-oxide (IGTO), or indium-gallium-oxide (IGO), but is not limited thereto. As described above, when the first active layer A1 and the second active layer A2 are implemented with an oxide semiconductor material, the first active layer A1 and the second active layer A2 may include an intrinsic channel area which is not doped with an impurity and a source area and a drain area which are doped with an impurity to become conductive.

The second insulating layer 112b may be disposed on the second active buffer layer 114bwhile covering the first active layer A1 and the second active layer A2. The second insulating layer 112bmay be a gate insulating film, and for example, may be formed of silicon oxide (SiOx), silicon nitride (SiNx), or a double film thereof.

The first gate electrode G1 of the first thin film transistor TR1 and the second gate electrode G2 of the second thin film transistor TR2 may be disposed to be spaced apart from each other on the second insulating layer 112b. In this case, the first gate electrode G1 is disposed on the second insulating layer 112b so as to overlap the first active layer A1, and the second gate electrode G2 is disposed on the second insulating layer 112b so as to overlap the second active layer A2.

The first gate electrode G1 and the second gate electrode G2 are disposed on the same layer and may be formed of the same material. For example, the first gate electrode G1 and the second gate electrode G2 may be formed of a conductive material such as magnesium (Mg), aluminum (Al), nickel (Ni), chromium (Cr), molybdenum (Mo), tungsten (W), gold (Au), or an alloy thereof, but are not limited thereto. In addition, at least one of the first blocking layer BSM1, the second blocking layer BSM2, the first capacitor electrode C1, and the second capacitor electrode C2 described above may be made of the same material as the first gate electrode G1 and the second gate electrode G2.

The second interlayer insulating layer 113b is disposed on the second insulating layer 112b while covering the first gate electrode G1 and the second gate electrode G2. For example, the second interlayer insulating layer 113b may be configured by a single layer of silicon nitride (SiNx) or silicon oxide (SiOx) or a multi-layer thereof.

The first source electrode and the first drain electrode D1 of the first transistor TR1 and the second source electrode S2 and the second drain electrode D2 of the second transistor TR2 are disposed on the second interlayer insulating layer 113b. The first source electrode, the first drain electrode D1, the second source electrode S2, and the second drain electrode D2 may each be formed of a single layer or a multi-layer formed of various conductive materials, such as magnesium (Mg), aluminum (Al), nickel (Ni), chromium (Cr), molybdenum (Mo), tungsten (W), gold (Au), or an alloy thereof, but are not limited thereto. Meanwhile, FIG. 4 illustrates a cross-sectional view of a partial area in which the sub pixel is cut in one direction (i.e., I-I'). Accordingly, the first source electrode of the first transistor TR1 is omitted in FIG. 4, but the first source electrode of the first transistor TR1 is disposed on the second interlayer insulating layer 113b and is electrically connected to the source area of the first active layer A1. This may be confirmed in a cross section in which the sub pixel is cut in a direction different from the direction I-I' of FIG. 2.

A portion of the first active layer A1 overlapping the first gate electrode G1 is a channel area, and one of the first source electrode and the first drain electrode D1 is connected to one side of the channel area in the first active layer A1, and the other is connected to the other side of the channel area in the first active layer A1. In this case, the first source electrode may be connected to one side (i.e., a source area) of the first active layer A1 through contact holes provided in the second insulating layer 112b and the second interlayer insulating layer 113b, and the first drain electrode D1 may be connected to the other side (i.e., a drain area) of the first active layer A1 through contact holes CH3 provided in the second insulating layer 112b and the second interlayer insulating layer 113b. In the second active layer A2, a portion overlapping the second gate electrode G2 is a channel area, and any one of the second source electrode S2 and the second drain electrode D2 is connected to one side of the channel area in the second active layer A2, and the other is connected to the other side of the channel area in the second active layer A2. In this case, the second source electrode S2 may be connected to one side (i.e., a source area) of the second active layer A2 through the contact hole CH7 provided in the second insulating layer 112b and the second interlayer insulating layer 113b, and the second drain electrode D2 may be connected to the other side (i.e., a drain area) of the second active layer A2 through the contact hole CH8 provided in the second insulating layer 112b and the second interlayer insulating layer 113b. In addition, the metallic pattern disposed on the same layer as the second source electrode S2 and connected to the second source electrode S2 or extending from the second source electrode S2 may be electrically connected to the second blocking layer BSM2 through the contact holes CH6 provided in the second insulating layer 112b, the second interlayer insulating layer 113b, and the second active buffer layer 114b.

A plurality of metal patterns are disposed on the second interlayer insulating layer 113b at positions different from the first source electrode, the first drain electrode D1, the second source electrode S2, and the second drain electrode D2, respectively. The plurality of metal patterns includes a first metal pattern SD1, a second metal pattern SD2, and a third metal pattern SD3. Further, the plurality of metal patterns may further include a fourth metal pattern, and in FIG. 4, it is illustrated as an example that the fourth metal pattern is integrated extending from one end of the second source electrode S2. The first metal pattern SD1 may be electrically connected to the first gate electrode G1 of the first thin film transistor TR1 through the contact hole CH2 provided in the second interlayer insulating layer 113b. For example, the first metal pattern SD1 may be a signal line which applies a gate signal applied through the gate line GL to the first gate electrode G1. Further, the first metal pattern SD1 may be electrically connected to the first blocking layer BSM1 through the contact hole CH1 provided in the second interlayer insulating layer 113b, the second insulating layer 112b, the second active buffer layer 114b, the second multi-buffer layer 114a, and the first interlayer insulating layer 113a. The second metal pattern SD2 may be electrically connected to the first capacitor electrode C1 through the contact hole CH4 provided in the second interlayer insulating layer 113b, the second insulating layer 112b, the second active buffer layer 114b, the second multi-buffer layer 114a, and the first interlayer insulating layer 113a. Further, the third metal pattern SD3 may be electrically connected to the second capacitor electrode C2 through the contact hole CH5 provided in the second interlayer insulating layer 113b, the second insulating layer 112b, the second active buffer layer 114b, and the second multi-buffer layer 114a. Each of the second metal pattern SD2 and the third metal pattern SD3 may be a signal pattern which electrically connects any one of the first capacitor electrode C1 and the second capacitor electrode C2 of the capacitor Cst to the source electrode of the thin film transistor and electrically connects the other one to the drain electrode. The connection relationship between the capacitor Cst and the driving transistor or the switching transistor may be changed depending on the driving method of the pixel driving circuit and the type of the thin film transistor.

The first planarization layer 115a and the second planarization layer 115b are sequentially disposed on the second interlayer insulating layer 113b. At this time, the first connection electrode CE may be disposed on the first planarization layer 115a, and the second planarization layer 115b may be disposed on the first connection electrode CE. The first connection electrode CE may be connected to the second drain electrode D2 through a contact hole provided in the first planarization layer 115a. However, the first connection electrode CE may be connected to the second source electrode S2 depending on the type of the thin film transistor or the like. The first planarization layer 115aand the second planarization layer 115b may be organic films for planarizing and protecting upper portions of the plurality of transistors. For example, the first planarization layer 115aand the second planarization layer 115b may be formed of an organic material such as acryl resin, epoxy resin, phenolic resin, polyamide resin, or polyimide resin. The first connection electrode CE may serve to electrically connect the thin film transistor and the first electrode 121 of the light emitting element 120. For example, the first connection electrode CE may be formed of a single film or a multi-film formed of any one of molybdenum (Mo), copper (Cu), titanium (Ti), aluminum (Al), chrome (Cr), gold (Au), nickel (Ni), and neodymium (Nd) or an alloy thereof, but is not limited thereto. The first connection electrode CE may be formed of the same material as the source electrode and the drain electrode of the thin film transistor.

The light emitting element 120 is disposed on the second planarization layer 115b. Further, a bank 116 defining the emission area of the plurality of sub pixels SP is disposed on the second planarization layer 115b.

The light emitting element 120 includes an anode electrode 121, an emission layer 122, and a cathode electrode 123. Referring to FIG. 4, for example, the bank 116 may include an opening that exposes a portion of the anode electrode 121 of the light emitting element 120 by opening a portion corresponding to the emission area of the sub pixel SP. Specifically, the anode electrode 121 of the light emitting element 120 is disposed on the second planarization layer 115b. The anode electrode 121 may be formed of a metallic material, and is connected to the first connection electrode CE through a contact hole provided in the second planarization layer 115b. Accordingly, the anode electrode 121 may be electrically connected to the second thin film transistor TR2. For example, the display device 100 according to one or more embodiments of the present disclosure may be implemented as a top emission type display device in which light emitted from the light emitting element 120 is emitted to the upper portion of the first substrate 110. In this case, the anode electrode 121 may further include a transparent conductive film and a reflective film on the transparent conductive film. For example, the transparent conductive film may be formed of a transparent conductive oxide such as ITO or IZO, and the reflective film may be formed of silver (Ag), aluminum (Al), gold (Au), molybdenum (Mo), tungsten (W), chrome (Cr), or an alloy thereof. The bank 116 is disposed on the second planarization layer 115b while covering both ends of the anode electrode 121, and a portion of the anode electrode 121 may be exposed through the opening of the bank 116. For example, the bank 116 may be formed of an inorganic insulating material or an organic insulating material, but is not limited thereto. The emission layer 122 of the light emitting element 120 is disposed at and around the opening of the bank 116. Accordingly, the emission layer 122 may be disposed on the anode electrode 121 exposed through the opening of the bank 116. For example, the emission layer 122 may include a plurality of organic films. Here, the emission layer 122 may apply an electroluminescent film and an inorganic emission layer.

The cathode electrode 123 is disposed on the emission layer 122 of the light emitting element 120. The cathode electrode 123 serves to supply electrons to the emission layer 122 and may be formed of a metal material such as magnesium (Mg) or silver-magnesium, which are conductive materials having a low work function, but is not limited thereto. For example, in the top emission type display device 100, the cathode electrode 123 may include indium tin oxide (ITO), indium zinc oxide (IZO), indium tin zinc oxide (ITZO), zinc oxide (ZnO), and tin oxide (TO) based transparent conductive oxides.

Meanwhile, the second substrate 150 is disposed above the first substrate 110. As illustrated in FIG. 4, a filling layer 140 which bonds the first substrate 110 and the second substrate 150 is disposed between the first substrate 110 and the second substrate 150. The filling layer 140 is disposed least in the first display area and the second display area. Specifically, the filling layer 140 is disposed on the light emitting element 120 disposed on the first substrate 110 to suppress moisture and oxygen permeation into the light emitting element 120 and the second substrate 150 covers and bonds the upper portion of the filling layer 140 to seal the light emitting element 120. For example, one surface of the filling layer 140 may be in contact with the cathode electrode 123 disposed on the first substrate 110, and the other surface may be in contact with the second overcoat layer 154 disposed below the second substrate 150. The color filter CF and the touch sensing unit TS are disposed below the second substrate 150.

Hereinafter, configurations stacked in a direction from a lower surface of the second substrate 150 toward the first substrate 110 will be described sequentially. That is, in the description of the components disposed on the second substrate 150 below, the expression “on” means substantially below the second substrate 150 in the downward direction (i.e., in the direction toward the first substrate 110).

The black matrix BM is disposed on a lower surface of the second substrate 150 (i.e., a surface facing the first substrate 110). The black matrix BM includes a plurality of openings corresponding to emission areas of the plurality of sub pixels SP so that the openings of each of the first touch electrode TE1 and the second touch electrode TE2, the opening of the bank 116, and the opening of the black matrix BM may overlap each other.

The first overcoat layer 151 is disposed on the lower surface of the second substrate 150 while covering the black matrix BM. The first overcoat layer 151 may be an organic layer for planarizing and protecting the lower portion of the black matrix BM.

A plurality of first touch electrodes TE1 and a plurality of second touch electrodes TE2 are disposed on a lower surface of the first overcoat layer 151. FIG. 4 illustrates a cross-section of a partial area in the second display area of the second substrate 150. Thus, only a touch electrode line of the second touch electrode TE2 is displayed. However, the touch electrode line of the first touch electrode TE1 and a bridge electrode connecting the unit electrodes of the first touch electrode TE1 may also be disposed on the same layer as the second touch electrode TE2. Touch electrode lines of each of the plurality of first touch electrodes TE1 and the plurality of second touch electrodes TE2 may be located under the black matrix BM disposed in the non-emission area between the sub pixels SP. In this case, the width of the touch electrode line of each of the first and second touch electrodes TE1 and TE2 may be equal to or less than the width between the openings of the black matrix BM. For example, the width of the touch electrode line of the plurality of first touch electrodes TE1 may be equal to or less than the width between adjacent openings among the plurality of openings of the black matrix BM. Accordingly, the plurality of first and second touch electrodes TE1 and TE2 may be disposed under the black matrix BM and may not be visible to the outside.

The touch interlayer insulating layer 152 is disposed on the lower surface of the first overcoat layer 151 while covering the plurality of first touch electrodes TE1 and the plurality of second touch electrodes TE2. Further, the plurality of second bridge electrodes BE is disposed on the lower surface of the touch interlayer insulating layer 152. The bridge electrode BE which electrically connects the unit electrodes of the second touch electrode TE2 is insulated from the first touch electrode TE1 and the bridge electrode which connects the unit electrodes of the first touch electrode TE1by the touch interlayer insulating layer 152. For example, in order to prevent the first touch electrode TE1 arranged in the first direction (i.e., the x-axis direction) and the plurality of second touch electrodes TE2 arranged in the second direction (i.e., the y-axis direction) from being short-circuited to each other in an area intersecting each other, the plurality of second touch electrodes TE2 extending in the second direction may be electrically connected through the bridge electrode BE disposed on the lower film. In this case, a contact hole for electrically connecting the second touch electrode TE2 and the bridge electrode BE may be formed in the touch interlayer insulating layer 152. In addition, the touch interlayer insulating layer 152 may be an inorganic film made of an inorganic material, but the constituent material is not limited thereto.

The passivation layer 153 is disposed on the lower surface of the touch interlayer insulating layer 152 to cover the bridge electrode BE. The passivation layer 153 may be an inorganic layer for protecting the plurality of first and second touch electrodes TE1 and TE2 and the plurality of bridge electrodes BE. For example, the passivation layer 153 may be made of silicon oxide (SiOx), silicon nitride (SiNx), or multiple layers thereof.

A plurality of color filters CF are disposed on the lower surface of the passivation layer 153. The plurality of color filters CF are disposed to overlap each of the emission areas for each of the plurality of sub pixels SP constituting one pixel. Accordingly, the plurality of color filters CF are disposed on different layers below the black matrix BM, and the black matrix BM is disposed between the plurality of color filters CF when viewed in a plan view. For example, when one pixel is implemented as a red sub pixel, a green sub pixel, and a blue sub pixel, the plurality of color filters CF may include a red color filter, a green color filter, and a blue color filter. The red color filter, the green color filter, and the blue color filter may be disposed so that one color filter corresponds to each emission area of the plurality of sub pixels to improve color reproducibility, but are not limited thereto.

Meanwhile, in FIG. 4, an example in which the plurality of color filters CF are disposed on a different layer from the black matrix BM has been described. However, the placement position of the plurality of color filters CF is not limited thereto. As another example, as illustrated in FIG. 5, the plurality of color filters CF' may be disposed on the same layer as the black matrix BM. In this case, the black matrix BM may be disposed between the plurality of color filters CF' on the plane, and a portion of the end of the black matrix BM and the color filter CF' may overlap.

Referring to FIG. 4, the second overcoat layer 154 is disposed on the lower surface of the passivation layer 153 while covering the plurality of color filters CF. The second overcoat layer 154 may be an organic layer for planarizing and protecting the lower portions of the plurality of color filters CF. For example, the second overcoat layer 154 may be formed of an organic material such as acryl resin, epoxy resin, phenolic resin, polyamide resin, and polyimide resin.

Due to the bonding of the second substrate 150 and the first substrate 110 having the above structure, a lower surface of the second overcoat layer 154 on the second substrate 150 may be in contact with the upper surface of the filling layer 140, and an upper surface of the cathode electrode 123 of the light emitting element 120 on the first substrate 110 and a portion of the upper surface of the second planarization layer 115b may be in contact with the lower surface of the filling layer 140.

Hereinafter, configurations stacked on an upper surface of the second substrate 150 (i.e., a surface opposite to the surface facing the first substrate 110) will be described. That is, in the description of the components disposed on the second substrate 150 below, the expression “on” means substantially above the second substrate 150 in the upward direction (i.e., a direction opposite to the direction toward the first substrate 110).

The polarizing plate 160, the adhesive layer 170, and the cover member 180 are sequentially disposed on the upper surface of the second substrate 150. The polarizing plate 160 is a layer for polarizing incident light, and may be, for example, a film having a predetermined level of light transmittance, and absorbs external light and reflected light thereof to prevent a decrease in contrast ratio. The cover member 180 is disposed on the upper portion of the polarizing plate 160, and the adhesive layer 170 is disposed between the polarizing plate 160 and the cover member 180. An optically clear adhesive (OCA) may be used as the adhesive layer 170 so as to minimize or reduce the generation of bubbles or foreign substances between the polarizing plate 160 and the cover member 180. The cover member 180 protects the display device 100 from external impacts, moisture, heat, and the like. For example, the cover member 180 may be a tempered glass having a high Young's modulus, but is not limited thereto.

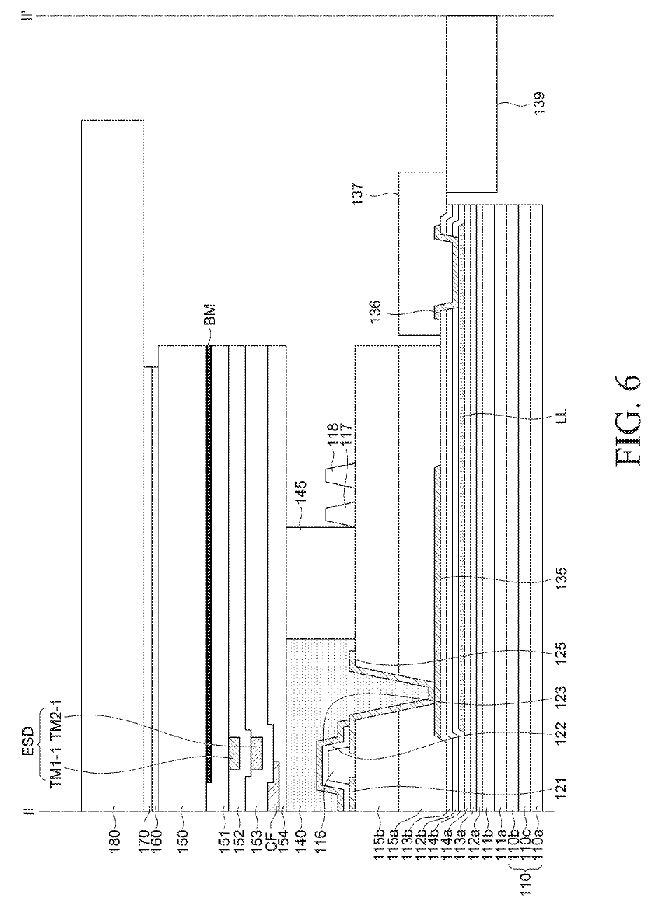

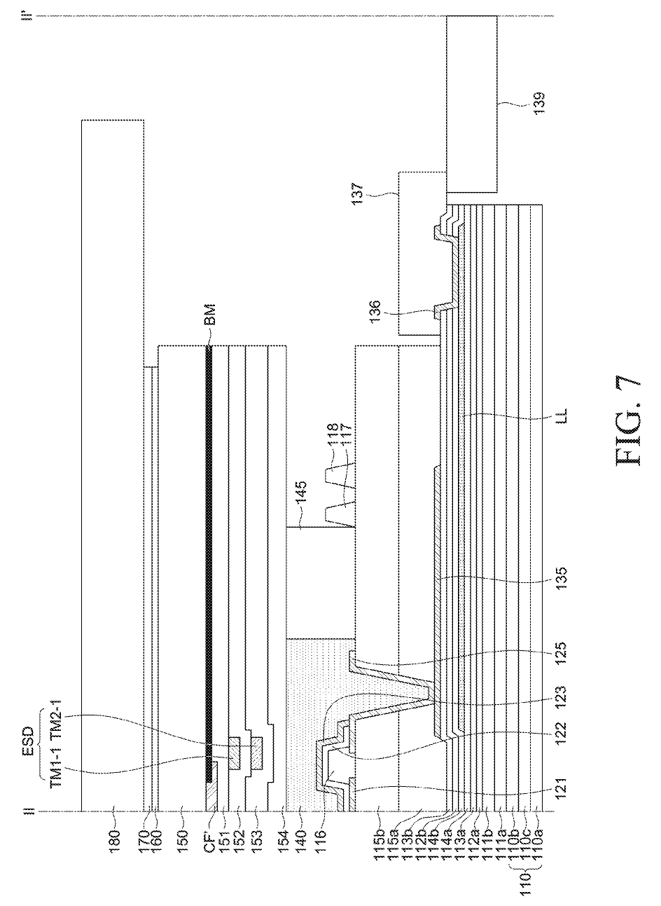

Hereinafter, a structure of the first non-display area NA1 of the first substrate 110 of the display device 100 according to one or more embodiments of the present disclosure will be described in detail with reference to FIGS. 6 and 7. The structure of the first non-display area NA1 of the first substrate 110 illustrated in FIG. 7 is substantially the same as the structure of the first non-display area NA1 of the first substrate 110 illustrated in FIG. 6 except for an arrangement position of the plurality of color filters CF'. Therefore, repeated descriptions thereof will be omitted.

FIG. 6 is an example of a cross-sectional view taken along line II-II' of FIG. 2.

FIG. 7 is another example of a cross-sectional view taken along line II-II' of FIG. 2.

Referring to FIG. 6, the signal link line LL is disposed on the second multi-buffer layer 114a. The signal link line LL electrically connects the sub pixel SP and the signal pad 136. The signal link line LL may be disposed on the same layer as the second blocking layer BSM2 disposed in the first display area DA and may be formed of the same material, but is not limited thereto. For example, the signal link line LL may be disposed on the same layer as the first blocking layer BSM1 disposed in the first display area DA and may be formed of the same material.

The second active buffer layer 114b is disposed on the second multi-buffer layer 114a while covering the signal link line LL. The second active buffer layer 114bmay include a contact hole which exposes a portion of the signal link line LL so that the signal pad 136 may be electrically connected to the signal link line LL.

The second insulating layer 112b and the second interlayer insulating layer 113b are sequentially disposed on the second active buffer layer 114b, and the second insulating layer 112b and the second interlayer insulating layer 113b may each include a contact hole which exposes a portion of the signal link line LL so that the signal pad 136 may be electrically connected to the signal link line LL.

A common line 135 for supplying a low potential power voltage supplied through the low potential power line VSS to the cathode electrode 123 of the light emitting element 120 is disposed on the second interlayer insulating layer 113b. FIG. 6 illustrates a cross-section of a partial area of the first non-display area NA1 of the first substrate 110. Thus, a connection portion between the low potential power line VSS and the common line 135 is omitted, but the common line 135 is electrically connected to the low potential power line VSS. Further, the common line 135 is electrically connected to an end of the cathode electrode 123 through the second connection electrode 125. The common line 135 is disposed on the same layer as the source electrode and the drain electrode of the thin film transistor disposed in the display area DA, and may be formed of the same material, but is not limited thereto. For example, the common line 135 may be disposed on the same layer as the gate electrode of the thin film transistor disposed in the display area DA and may be formed of the same material.

The first planarization layer 115a is disposed on the second interlayer insulating layer 113b while covering the common line 135. The first planarization layer 115amay include a contact hole so that the second connection electrode 125 may be electrically connected to the common line 135. The first planarization layer 115aextends from the first display area DA of the first substrate 110 and is disposed only up to a position inwardly spaced by a predetermined distance from the outermost portion of the first non-display area NA1 of the first substrate 110 to expose the outer peripheral portion of the second interlayer insulating layer 113b. The second planarization layer 115b is disposed on the first planarization layer 115a. The second planarization layer 115bmay include a contact hole so that the second connection electrode 125 may be electrically connected to the common line 135. The second planarization layer 115bextends from the first display area DA of the first substrate 110 and is disposed only up to a position inwardly spaced by a predetermined distance from the outermost portion of the first non-display area NA1 of the first substrate 110 to expose the outer peripheral portion of the second interlayer insulating layer 113b.

The second connection electrode 125 is disposed on the second planarization layer 115b. The second connection electrode 125 is electrically connected to the common line 135 through contact holes formed in the first planarization layer 115a and the second planarization layer 115b, respectively. For example, the second connection electrode 125 may be disposed on the same layer and made of the same material as the anode electrode 121 of the light emitting element 120 disposed in the first display area DA of the first substrate 110. One end portion of the second connection electrode 125 may be disposed below the bank 116 disposed at the outermost side of the first display area DA of the first substrate 110, and the filling layer 140 may be filled on the second connection electrode 125 disposed inside the contact hole formed in each of the first planarization layer 115a and the second planarization layer 115b. The other end portion of the second connection electrode 125 may also be covered with the filling layer 140. In this case, the filling layer 140 may be disposed on the second planarization layer 115bexposed outside the other end of the second connection electrode 125.

Further, at least one dam 145 is disposed on the second planarization layer 115b so as to enclose the outer surface of the filling layer 140 and at least one blocking structure 117 and 118 is disposed outside the dam 145 and is disposed in the first non-display area of the first substrate 110. The dam 145 may be disposed to be in contact with the second planarization layer 115b o and the second overcoat layer 154, respectively, to confine the filling layer 140 therein. The dam 145 may include a material having adhesiveness, having a constant transmittance, capable of curing, and capable of width management that may be disposed by a dispensing process. The blocking structures 117 and 118 may be disposed to be adjacent to the dam 145 from the outer periphery of the dam 145 to prevent the material of the dam 145 from overflowing to the outside during the process of disposing the dam 145. For example, the blocking structures 117 and 118 may be disposed on the same layer and made of the same material as the bank 116 disposed in the first display area DA of the first substrate 110.

Further, the signal pad 136 is disposed on the second interlayer insulating layer 113b. The signal pad 136 is disposed at an outer portion of the second interlayer insulating layer 113b exposed to the first planarization layer 115a and the second planarization layer 115b, such that the signal pad 136 may be disposed at an outer portion of the first non-display area NA1 of the first substrate 110. The signal pad 136 is disposed on the same layer as the source electrode and the drain electrode of the thin film transistor disposed in the first display area DA, and may be formed of the same material. Further, the signal pad 136 is disposed on the same layer as the gate electrode of the thin film transistor disposed in the first display area DA, and may be formed of the same material.

A first flexible film 137 on which a driving integrated circuit such as a gate driver and a data driver is mounted is attached to the signal pad 136 to be electrically connected in the first non-display area NA1 of one side of the first substrate 110 (hereinafter, referred to as a "first side portion")." In addition, one end of the first flexible film 137 is connected to the signal pad 136, and the other end is electrically connected to a first circuit board 139 on which a plurality of circuits implemented by a plurality of driving chips, such as a timing controller, are mounted. For example, one end of the signal pad 136 and one end of the first flexible film 137 and the other end of the first flexible film 137 and the circuit board 139 may be bonded through an adhesive layer such as an anisotropic conductive film (ACF) including conductive balls.

Meanwhile, referring to FIGS. 2 and 6 together, in one side portion (hereinafter, referred to as “second side portion”) of the second substrate 150 corresponding to the first side portion on which the signal pad 136 of the first substrate 110 is disposed, the touch routing line TRL is not disposed in the second non-display area NA2, and the electrostatic discharge circuit ESD is disposed. Specifically, in the second side portion of the second substrate 150, the black matrix BM expanded from the second display area of the second substrate 150, the first overcoat layer 151, the touch interlayer insulating layer 152, the passivation layer 153, and the second overcoat layer 154 are sequentially disposed in the second non-display area NA2 on the lower surface of the second substrate 150. Further, on the second side portion of the second substrate 150, an electrostatic discharge circuit ESD including a first layer TM1-1 disposed on the lower surface of the first overcoat layer 151 and a second layer TM2-1 disposed on the lower surface of the touch interlayer insulating layer 152 is disposed. The electrostatic discharge circuit ESD may overlap the black matrix BM. The first layer TM1-1 of the electrostatic discharge circuit ESD may be disposed on the same layer as the first and second touch electrodes TE1 and TE2 disposed in the second display area of the second substrate 150 and may be formed of the same material. Further, the second layer TM2-1 of the electrostatic discharge circuit ESD is disposed on the same layer as the bridge electrode BE disposed in the second display area of the second substrate 150 and may be formed of the same material. For example, the first layer TM1-1 and the second layer TM2-1 of the electrostatic discharge circuit ESD overlap each other, but may be electrically connected in at least one part. FIG. 6 illustrates a cross-section of a partial area of the second non-display area NA2 of the second substrate 150 corresponding to a partial area of the first non-display area NA1 of the first substrate 110. Thus, portions where the first layer TM1-1 and the second layer TM2-1 of the electrostatic discharge circuit ESD are electrically connected to each other are omitted, but the first layer TM1-1 and the second layer TM2-1 of the electrostatic discharge circuit ESD may be electrically connected through a contact hole formed in the touch interlayer insulating layer 152 in at least a partial area. Accordingly, the resistance of the electrostatic discharge circuit ESD may be reduced.

Further, referring to FIGS. 4 and 6 together, the color filter CF is disposed on the lower surface of the passivation layer 153 of the second substrate 150. In this case, the electrostatic discharge circuit ESD may be disposed adjacent to the outermost side of the first display area DA of the first substrate 110. For example, the electrostatic discharge circuit ESD may be disposed so that at least a portion of the bank 116 and the end of the color filter CF corresponding to the light emitting element 120 disposed at the outermost side of the first display area DA of the first substrate 110 overlap. Meanwhile, in FIG. 6, an example in which the plurality of color filters CF is disposed on a different layer from the black matrix BM has been described. However, the placement position of the plurality of color filters CF is not limited thereto. As another example, as illustrated in FIG. 7, the plurality of color filters CF' may be disposed on the same layer as the black matrix BM. In this case, the black matrix BM may be disposed between the plurality of color filters CF' on the plane, and the electrostatic discharge circuit ESD may be disposed to overlap at least a portion of an end portion of the color filter CF', the black matrix BM, and the bank 116 corresponding to the light emitting element disposed at the outermost side of the first display area DA of the first substrate 110 .

Referring to FIG. 6, in the display device 100 according to one or more embodiments of the present disclosure, an outer portion of the first substrate 110 may further protrude outward from the first side portion of the first substrate 110 than an outermost portion of the second substrate 150. In this way, it is possible to attach the signal pad 136 and the first flexible film 137 disposed on the first substrate 110 in an area further protruding to the outside than the outermost portion of the second substrate 150, so that the signal pad 136 and the first flexible film 137 may be easily attached in a state in which the first substrate 110 and the second substrate 150 are bonded, and damage to the signal pad 136 and the first flexible film 137 may also be prevented.

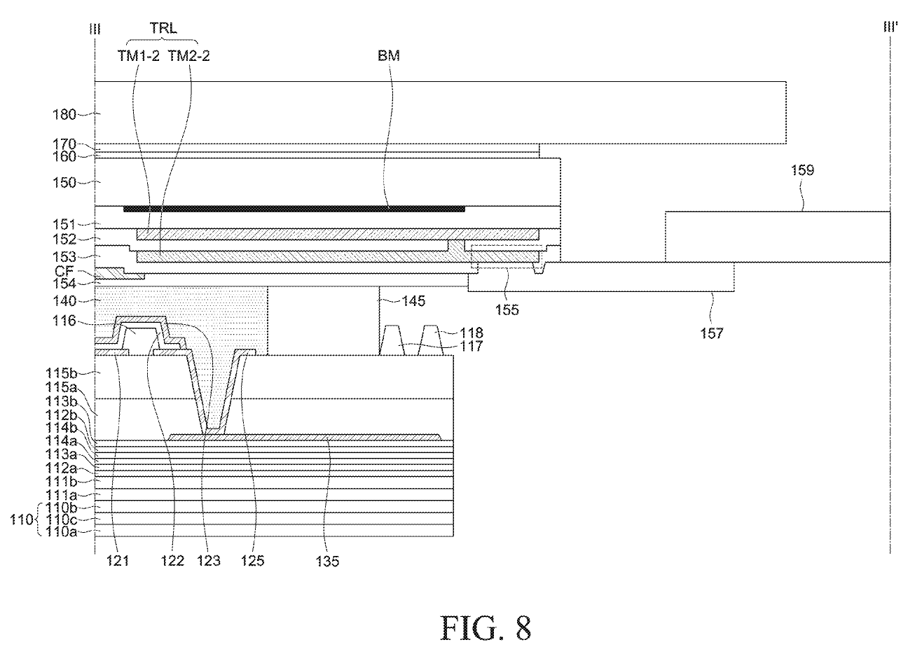

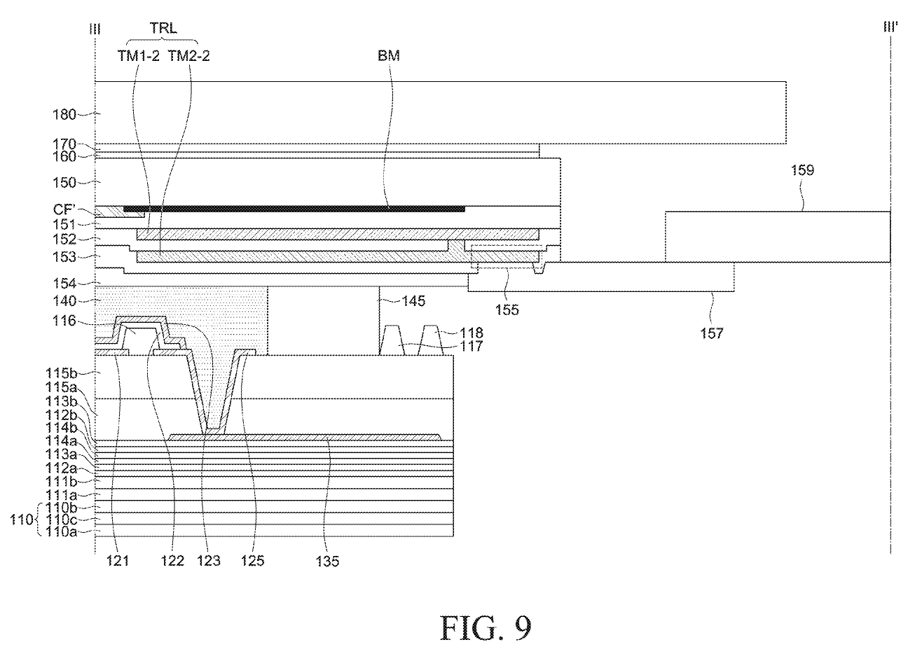

Hereinafter, with reference to FIGS. 8 and 9, a structure of a second non-display area NA2 in the other side portion of the second substrate 150 of a display device 100 according to one or more embodiments of the present disclosure will be described in detail, the other side portion being hereinafter referred to as a “third side portion”. The third side portion is a side portion of the second substrate 150 that does not overlap a first side portion of the first substrate 110. For example, referring to FIG. 2, the third side portion of the second substrate 150 and the first side portion of the first substrate 110 may face each other on a plane. The structure of the second non-display area NA2 of the second substrate 150 illustrated in FIG. 9 is substantially the same as the structure of the second non-display area NA2 of the second substrate 150 illustrated in FIG. 8 except for an arrangement position of the plurality of color filters CF'. Therefore, repeated descriptions thereof will be omitted.

FIG. 8 is an example of a cross-sectional view taken along line III-III' of FIG. 3.

FIG. 9 is another example of a cross-sectional view taken along line III-III' of FIG. 3.

Referring to FIGS. 2, 3, and 8 together, the touch routing line TRL and the touch pad 155 are disposed in the second non-display area NA2 below the second substrate 150 on the third side of the second substrate 150. Specifically, in the third side portion of the second substrate 150, the black matrix BM expanded from the second display area of the second substrate 150, the first overcoat layer 151, the touch interlayer insulating layer 152, the passivation layer 153, and the second overcoat layer 154 are sequentially disposed in the second non-display area NA2 of the lower surface of the second substrate 150. At this time, a touch routing line TRL including a first layer TM1-2 disposed on a lower surface of the first overcoat layer 151 and a second layer TM2-2 disposed on a lower surface of the touch interlayer insulating layer 152 is disposed in the second non-display area NA2 below the second substrate 150. The first layer TM1-2 of the touch routing line TRL may be disposed on the same layer as the first and second touch electrodes TE1 and TE2 disposed in the second display area of the second substrate 150 and may be formed of the same material. Further, the second layer TM2-2 of the touch routing line TRL may be disposed on the same layer as the bridge electrode BE disposed in the second display area of the second substrate 150 and may be formed of the same material. At least a portion of the touch routing line TRL may overlap the black matrix BM. For example, the first layer TM1-2 and the second layer TM2-2 of the touch routing line TRL overlap each other, but may be electrically connected in at least one part. The touch interlayer insulating layer 152 may include a contact hole to electrically connect the first layer TM1-2 and the second layer TM2-2 of the touch routing line TRL. Accordingly, the resistance of the touch routing line TRL may be reduced, and electrical connection between the touch pad 155 and the second flexible film 157 disposed below the second substrate 150 may be facilitated.

The touch pad 155 is disposed in the second non-display area NA2 below the second substrate 150 and in an outer portion of the second non-display area NA2. The touch pad 155 may be disposed on the same layer as the second layer TM2-2 of the touch routing line TRL and the bridge electrode BE disposed in the second display area of the second substrate 150 and may be formed of the same material. For example, the touch pad 155 may be integrally implemented with the second layer TM2-2 of the touch routing line TRL. In this case, the touch pad 155 may extend from one end of the second layer TM2-2 of the touch routing line TRL.

The passivation layer 153 is disposed on the lower surface of the touch interlayer insulating layer 152 while covering the second layer TM2-2 of the touch routing line TRL and the touch pad 155, and the color filter CF is disposed on the lower surface of the passivation layer 153. Further, the second overcoat layer 154 is disposed on the lower surface of the passivation layer 153 while covering the color filter CF. In FIG. 8, an example in which the color filter CF is disposed on a layer different from that of the black matrix BM has been described. However, the placement position of the color filter CF is not limited thereto, and as another example, as illustrated in FIG. 9, the color filter CF' may be disposed on the same layer as the black matrix BM. In this case, the touch routing line TRL may be disposed to partially overlap the end of the color filter CF', the black matrix BM, and the bank 116 corresponding to the light emitting element disposed at the outermost side of the first display area DA of the first substrate 110.

Referring to FIG. 8, under the second non-display area NA2 of the third side portion of the second substrate 150, a second flexible film 157 on which an integrated circuit such as a touch driving circuit is mounted is attached to a touch pad 155 to be electrically connected. Further, one end of the second flexible film 157 is connected to the touch pad 155, and the other end is attached to and electrically connected to the second circuit board 159 on which a plurality of circuits implemented by a plurality of driving chips such as a touch controller are mounted. For example, one end of the touch pad 155 and one end of the second flexible film 157, the other end of the second flexible film 157, and the second circuit board 159 may be bonded through an adhesive layer such as an anisotropic conductive film (ACF) including conductive balls. At the third side portion of the second substrate 150, the passivation layer 153 and the second overcoat layer 154 may each include a contact hole which exposes at least a portion of the touch pad 155 so that the touch pad 155 may be electrically connected to the second flexible film 157.

Referring to FIG. 8, in the display device 100 according to one or more embodiments of the present disclosure, an outer portion of the second substrate 150 may further protrude outward from the third side portion of the second substrate 150 than an outermost portion of the first substrate 110. As described above, the touch pad 155 and the second flexible film 157 disposed in an area further protruding outward from the outermost portion of the first substrate 110 below the second substrate 150 may be attached, such that the touch pad 155 and the second flexible film 157 may be easily attached in a state in which the first substrate 110 and the second substrate 150 are bonded, and damage to the touch pad 155 and the second flexible film 157 may also be prevented.

Further, referring to FIG. 8, on the third side portion of the second substrate 150, the black matrix BM may extend from the second display area of the second substrate 150 and may be disposed only up to a position spaced inward by a predetermined distance from the outermost portion of the second substrate 150. Accordingly, when the second flexible film 157 is attached on the lower side of the second substrate 150, an alignment mark for alignment or positioning between the touch pad 155 and the second flexible film 157 may be easily identified, and an indentation of the anisotropic conductive film (ACF) may also be easily identified.

Meanwhile, referring to FIGS. 6 and 8 together, the signal link line LL and the signal pad 136 are not disposed in the first non-display area NA1 of the first substrate 110 at the other side of the first substrate 110 corresponding to the third side of the second substrate 150, and accordingly, the first flexible film 137 and the first circuit board 139 are not attached to the other side of the first substrate 110. Except for the structural difference, the structure of the first non-display area NA1 on the other side of the first substrate 110 illustrated in FIG. 8 is substantially the same as the structure of the first non-display area NA1 on the first side of the first substrate 110 described in FIG. 6, so that a redundant description will be omitted.

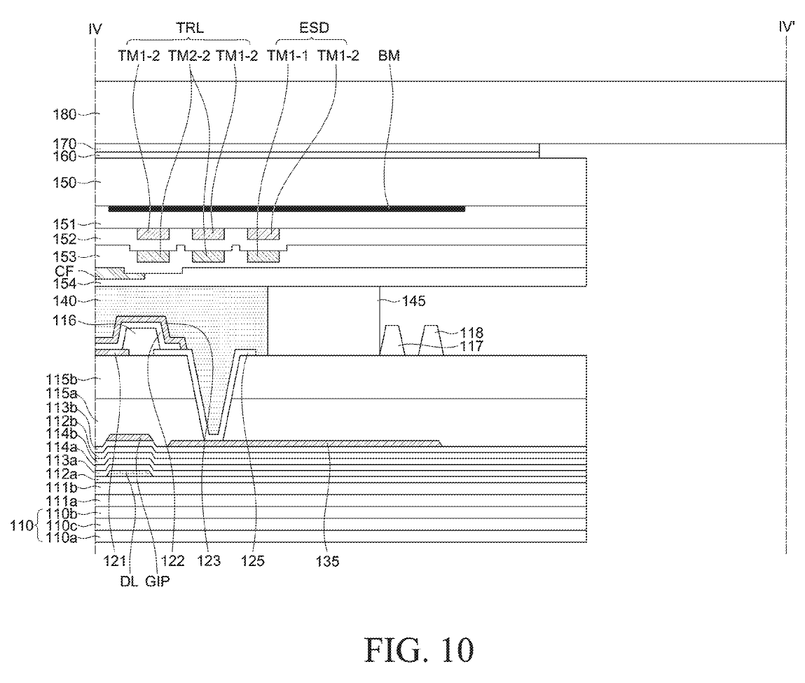

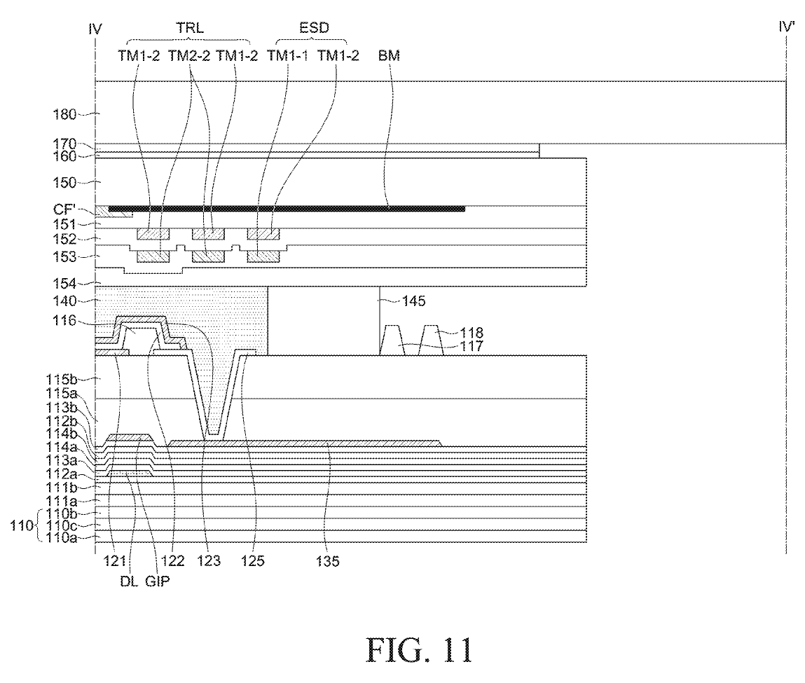

Hereinafter, a structure of the second non-display area NA2 in the other side portion (hereinafter, referred to as “fourth side portion”) non-overlapping with the first side portion of the first substrate 110 and the third side portion of the second substrate 150, among the side portions of the second substrate 150 of the display device 100 according to one or more embodiments of the present disclosure, will be described in detail with reference to FIGS. 10 and 11. For example, referring to FIGS. 2 and 3 together, on the plane, the third side portion of the second substrate 150 and the first side portion of the first substrate 110 face each other along the y-axis direction, and on the plane, the fourth side portion of the second substrate 150 may mean a side portion in a direction intersecting the third side portion of the second substrate 150 and the first side portion of the first substrate 110 along the x-axis direction. The structure of the second non-display area NA2 of the second substrate 150 illustrated in FIG. 11 is substantially the same as the structure of the second non-display area NA2 of the second substrate 150 illustrated in FIG. 10 except for an arrangement position of the plurality of color filters CF', so that a redundant description will be omitted.

FIG. 10 is an example of a cross-sectional view taken along line IV-IV' of FIG. 3.

FIG. 11 is another example of a cross-sectional view taken along line IV-IV' of FIG. 3.

Referring to FIGS. 8 and 10 together, the data line DL and the gate driving circuit GIP are disposed in the first non-display area NA1 of the first substrate 110 at the other side of the first substrate 110 corresponding to the fourth side of the second substrate 150. In this case, the data line DL is disposed on the second insulating layer 112b, and the gate driving circuit GIP is disposed on the second interlayer insulating layer 113b. The data line DL disposed in the first non-display area NA1 of the first substrate 110 is electrically connected to the plurality of sub pixels SP disposed in the first display area DA of the first substrate 110, and for example, may be disposed on the same layer and made of the same material as the first blocking layer BSM1 disposed in the first display area DA of the first substrate 110. Further, the gate driving circuit GIP disposed in the first non-display area NA1 of the first substrate 110 may be implemented by one or more thin film transistors. For example, the gate driving circuit GIP is disposed on the same layer as the active layer, the gate electrode, the source electrode, and the drain electrode of the thin film transistor disposed in the first display area DA of the first substrate 110 and may be formed of the same material, but is not limited thereto. FIG. 10 illustrates a cross-sectional view of a partial area in which the non-display areas of the first substrate 110 and the second substrate 150 are cut in one direction (i.e., IV-IV’). Accordingly, in FIG. 10, the remaining components other than the metal pattern GIP corresponding to the source electrode or the drain electrode, which are a portion of the components for implementing the gate driving circuit GIP, are omitted, but the gate driving circuit GIP further includes an active layer and a gate electrode. In addition, the gate driving circuit GIP may implement an active layer using an oxide semiconductor. Except for the structural difference, the structure of the first non-display area NA1 on the other side of the first substrate 110 illustrated in FIG. 10 (i.e., corresponding to the fourth side of the second substrate 150) is substantially the same as the structure of the first non-display area NA1 on the other side of the first substrate 110 described in FIG. 8, so that a redundant description will be omitted.

Referring to FIGS. 2, 3, 8, and 10 together, the touch routing line TRL and the electrostatic discharge circuit ESD are disposed in the second non-display area NA2 below the second substrate 150 on the fourth side of the second substrate 150. Specifically, in the fourth side portion of the second substrate 150, the black matrix BM expanded from the second display area of the second substrate 150, the first overcoat layer 151, the touch interlayer insulating layer 152, the passivation layer 153, and the second overcoat layer 154 are sequentially disposed in the second non-display area NA2 of the lower surface of the second substrate 150. At this time, a touch routing line TRL including a first layer TM1-2 disposed on a lower surface of the first overcoat layer 151 and a second layer TM2-2 disposed on a lower surface of the touch interlayer insulating layer 152 is disposed in the second non-display area NA2 below the second substrate 150. Further, an electrostatic discharge circuit ESD including a first layer TM1-1 disposed on a lower surface of the first overcoat layer 151 and a second layer TM2-1 disposed on a lower surface of the touch interlayer insulating layer 152 is disposed in the second non-display area NA2 below the second substrate 150.

Referring to FIGS. 3 and 10, in a fourth side portion of the second substrate 150, a plurality of touch routing lines TRL including a first layer TM1-2 and a second layer TM2-2,

respectively, is disposed in the second non-display area NA2 of the second substrate 150 so as to be adjacent to the second display area of the second substrate 150. Further, at a fourth side portion of the second substrate 150, an electrostatic discharge circuit ESD including a first layer TM1-1 and a second layer TM2-1 is disposed between an outermost touch routing line TRL among the plurality of touch routing lines TRL and an outermost portion of the second substrate 150, and the electrostatic discharge circuit ESD may be disposed to be adjacent to the outermost touch routing line TRL. In this case, at least a portion of the inner touch routing line TRL disposed closest to the second display area of the second substrate 150 may overlap the black matrix BM. Further, referring to FIG. 10, in the fourth side portion of the second substrate 150, the color filter CF is disposed on the lower surface of the passivation layer 153 and the second overcoat layer 154 is disposed on the lower surface of the passivation layer 153 while covering the color filter CF. FIG. 10 illustrates an example in which the color filter CF is disposed on a different layer from the black matrix BM. However, the arrangement position of the color filter CF is not limited thereto. As another example, as illustrated in FIG. 11, the color filter CF' may be disposed on the same layer as the black matrix BM. In this case, the inner touch routing line TRL disposed to be most adjacent to the second display area of the second substrate 150 may be disposed to partially overlap the end of the color filter CF', the black matrix BM, and the bank 116 corresponding to the light emitting element disposed at the outermost side of the first display area DA of the first substrate 110. Further, referring to FIG. 10, in the fourth side portion of the second substrate 150, in the display device 100 according to one or more embodiments of the present disclosure, the outermost portion of the second substrate 150 and the outermost portion of the first substrate 110 may be on the same horizontal plane.

A structure in the second non-display area NA2 on the fourth side of the second substrate 150 illustrated in FIG. 10 is substantially the same as the structure in the second non-display area NA2 on the third side of the second substrate 150 described in FIG. 8, except for the above structural difference, so that a redundant description will be omitted.

As described above, the display device 100 according to one or more embodiments of the present disclosure includes side portions (hereinafter, referred to as “non-overlapping side portions”) in which the display substrate 110 and the encapsulation substrate 150 facing each other are non-overlapping, and the signal pad 136 and the first flexible film 137 may be attached in a non-display area of the non-overlapping side of the display substrate 110, and the touch pad 155 and the second flexible film 157 may be attached in a non-display area of the non-overlapping side of the encapsulation substrate 150. Accordingly, even in a state in which the display substrate 110 and the encapsulation substrate 150 facing each other are bonded, easy attachment is possible without damage to the pad and the flexible film.

Further, in the display device 100 according to one or more embodiments of the present disclosure, the touch sensing unit TS and the color filters CF and CF' are provided on the encapsulation substrate 150. The touch pad 155 may be implemented as a layer which is disposed on the same layer and made of the same material as the touch electrodes TE1 and TE2 of the touch sensing unit TS and the bridge electrode BE disposed on a different layer from the touch electrodes TE1 and TE2. Accordingly, the resistance of the touch pad 155 may be reduced, and the touch pad 155 and the second flexible film 157 may be easily attached.

The embodiments of the present disclosure can also be described as follows:

According to one or more embodiments of the present disclosure, a display device comprises a first substrate including a first display area in which a plurality of sub pixels is disposed and a first non-display area outside the first display area, a second substrate which is opposite to the first substrate on an upper portion of the first substrate and includes a second display area corresponding to the first display area and a second non-display area outside the second display area, a plurality of first pads disposed in the first non-display area of the first substrate, a plurality of touch electrodes disposed in the second display area under the second substrate, a plurality of bridge electrodes disposed in the second display area under the second substrate, disposed on a different layer from the plurality of touch electrodes, and electrically connected to a portion of the plurality of touch electrodes and a plurality of second pads disposed in the second non-display area under the second substrate and electrically connected to each of the plurality of touch electrodes, the plurality of first pads is disposed on one side portion of the first substrate and the plurality of second pads is disposed on the other side portion of the second substrate that does not overlap with one side portion of the first substrate.

According to one or more embodiments of the present disclosure, the display device may further include a first flexible film on the plurality of first pads and electrically connected to the plurality of first pads at one side portion of the first substrate; and a second flexible film under the plurality of second pads and electrically connected to the plurality of second pads at the other side portion of the second substrate.

According to one or more embodiments of the present disclosure, the display device may further include a black matrix which is disposed on a lower surface of the second substrate and does not overlap the emission area of the light emitting element included in each of the plurality of sub pixels; a first overcoat layer disposed below the second substrate so as to cover the black matrix; a touch interlayer insulating layer disposed below the first overcoat layer; a passivation layer disposed below the touch interlayer insulating layer; and a second overcoat layer disposed below the passivation layer. In this case, the plurality of touch electrodes may be disposed on a lower surface of the first overcoat layer, and the plurality of bridge electrodes may be disposed on a lower surface of the touch interlayer insulating layer.

According to one or more embodiments of the present disclosure, the display device may further include a plurality of touch routing lines which is disposed in the second non-display area of the second substrate and electrically connects the plurality of touch electrodes and the plurality of second pads. In this case, the plurality of touch routing lines may include a first layer disposed on the same layer as the plurality of touch electrodes, and a second layer disposed on the same layer as the plurality of bridge electrodes and electrically connected to the first layer.

According to one or more embodiments of the present disclosure, an end of the second flexible film is electrically connected to the plurality of second pads, and a portion of the end of the second flexible film may be disposed on a lower side of the second overcoat layer .

According to one or more embodiments of the present disclosure, the plurality of second pads may extend from one end of the second layer of the plurality of touch routing lines.

According to one or more embodiments of the present disclosure, the display device may further include a plurality of color filters disposed on a lower surface of the passivation layer under the second substrate and disposed to overlap the emission areas of the plurality of sub pixels.

According to one or more embodiments of the present disclosure, the display device may further include a plurality of color filters disposed on the same layer as the black matrix under the second substrate and disposed to overlap the emission areas of the plurality of sub pixels.

According to one or more embodiments of the present disclosure, the black matrix may be disposed on the other side portion of the second substrate up to a position spaced inward from the outermost portion of the second substrate by a predetermined distance.

According to one or more embodiments of the present disclosure, the second non-display area on the other side of the second substrate may protrude more than the outermost periphery of the first substrate.

According to one or more embodiments of the present disclosure, at one side portion of the first substrate, the first non-display area may protrude more than the outermost edge of the second substrate.

According to one or more embodiments of the present disclosure, the display device may further include a blocking layer disposed in the first display area on an upper portion of the first substrate; a thin film transistor disposed on the blocking layer in the first display area of the first substrate and including an active layer, a gate electrode, a source electrode, and a drain electrode; and a plurality of signal link lines disposed in the first non-display area on one side portion of the first substrate and electrically connecting the plurality of sub pixels and the plurality of first pads. In this case, the light emitting element may include a first electrode disposed on the thin film transistor, an emission layer disposed on the first electrode, and a second electrode disposed on the emission layer, and the plurality of first pads is disposed on the same layer as one of the gate electrode, the source electrode, and the drain electrode and includes the same material, and the plurality of signal link lines is disposed on the same layer as the blocking layer and includes the same material.

According to one or more embodiments of the present disclosure, the display device includes: a thin film transistor which is disposed in the first display area at an upper portion of the first substrate and includes an active layer, a gate electrode, a source electrode, and a drain electrode, and is electrically connected to a light emitting element; a planarization layer disposed on the thin film transistor; a bank which is disposed on the planarization layer and has an open portion corresponding to the emission area; a filling layer disposed on at least the first display area and the second display area between the first substrate and the second substrate; a dam which is disposed between the first substrate and the second substrate while surrounding an outer surface of the filling layer between the first substrate and the second substrate; and at least one blocking structure disposed in the first non-display area of the first substrate and disposed adjacent to the dam outside the dam, wherein the at least one blocking structure is disposed on the same layer as the bank and is formed of the same material.

A display device according to one or more other embodiments of the present disclosure includes a first substrate including a display area in which a plurality of light emitting elements is disposed, and a non-display area outside the display area; a second substrate which is opposite to the first substrate from an upper portion of the first substrate; a filling layer disposed between the first substrate and the second substrate; at least one dam which is disposed between the first substrate and the second substrate to surround an outer surface of the filling layer to confine the filling layer; a plurality of first touch electrodes which is disposed in a first area corresponding to the display area under the second substrate and extends in a first direction and a plurality of second touch electrodes which extends in a second direction intersecting the first direction; a plurality of bridge electrodes which is disposed in the first area under the second substrate and is disposed on a different layer from the plurality of first touch electrodes and the plurality of second touch electrodes and is electrically connected to a portion of the plurality of second touch electrodes; a plurality of touch routing lines which extends from the first area and is disposed in the second area at least partially overlapping the non-display area; a plurality of touch pads which extends from the second area and is disposed in the third area non-overlapping with non-display area at one side of the second substrate; and a second flexible film which is electrically connected to the plurality of touch pads at a lower portion of the second substrate.

According to one or more other embodiments of the present disclosure, the plurality of touch routing lines may include a first layer disposed on the same layer as the plurality of first touch electrodes and the plurality of second touch electrodes; and a second layer disposed on the same layer as the plurality of bridge electrodes and electrically connected to the first layer. In this case, the plurality of touch pads may extend from one end portion of the second layer of the plurality of touch routing lines.

According to one or more other embodiments of the present disclosure, the display device may further include a plurality of color filters disposed under the second substrate and disposed to overlap the emission areas of the plurality of light emitting elements; and a black matrix disposed under the second substrate and disposed to non-overlapping with the emission areas of the plurality of light emitting elements. In this case, at one side of the second substrate, the black matrix may be disposed from the outermost portion of the second substrate to a position spaced inward by a predetermined distance.

According to one or more other embodiments of the present disclosure, the third area on one side of the second substrate may protrude more than the outermost side of the first substrate.

According to one or more other embodiments of the present disclosure, the display device may further include a plurality of signal pads disposed in the non-display area on the other side of the first substrate that does not overlap one side of the second substrate; a plurality of signal link lines disposed in the non-display area at the other side of the first substrate and electrically connecting the plurality of signal pads and a plurality of sub pixels disposed with the plurality of light emitting elements respectively; and a first flexible film electrically connected to the plurality of signal pads at an upper portion of the first substrate.

According to one or more other embodiments of the present disclosure, the non-display area on the other side of the first substrate may protrude more than the outermost periphery of the second substrate.

According to one or more other embodiments of the present disclosure, the plurality of color filters may be disposed on the same layer as the black matrix.

According to one or more other embodiments of the present disclosure, the display device may further include a first overcoat layer disposed below the second substrate so as to cover the black matrix; a touch interlayer insulating layer disposed below the first overcoat layer; and a passivation layer disposed below the touch interlayer insulating layer, wherein the plurality of color filters are disposed on a lower surface of the passivation layer.

Although the embodiments of the present disclosure have been described in detail with reference to the accompanying drawings, the present disclosure is not limited thereto and may be embodied in various forms without departing from the technical concept of the present disclosure. Therefore, the embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all embodiments and do not limit the present disclosure. All the technical concepts in the equivalent scope of the present disclosure should be construed as falling within the scope of the present disclosure.

What is claimed is:

1. A display device, comprising:
a first substrate including a first display area in which a plurality of sub pixels is disposed and a first non-display area outside the first display area;
a second substrate which is opposite to the first substrate on the first substrate, the second substrate including a second display area corresponding to the first display area and a second non-display area outside the second display area;
a plurality of first pads disposed in the first non-display area of the first substrate;
a plurality of touch electrodes disposed in the second display area below the second substrate;
a plurality of bridge electrodes disposed in the second display area below the second substrate, the plurality of bridge electrodes disposed on a different layer from the plurality of touch electrodes, and the plurality of bridge electrodes electrically connected to some of the plurality of touch electrodes; and
a plurality of second pads disposed in the second non-display area below the second substrate, the plurality of second pads electrically connected to each of the plurality of touch electrodes,
wherein the plurality of first pads is disposed on a first side portion of the first substrate, and
wherein the plurality of second pads is disposed on a second side portion of the second substrate that does not overlap with the first side portion of the first substrate.

2. The display device according to claim 1, further comprising:
a first flexible film on the plurality of first pads, the first flexible film electrically connected to the plurality of first pads at the first side portion of the first substrate; and
a second flexible film under the plurality of second pads, the second flexible film electrically connected to the plurality of second pads at the second side portion of the second substrate.

3. The display device of claim 2, further comprising:
a black matrix disposed on a lower surface of the second substrate and non-overlapping with an emission area of a light emitting element included in each of the plurality of sub pixels;
a first overcoat layer disposed below the second substrate so as to cover the black matrix;
a touch interlayer insulating layer disposed below the first overcoat layer;
a passivation layer disposed below the touch interlayer insulating layer; and
a second overcoat layer disposed below the passivation layer,
wherein the plurality of touch electrodes is disposed on a lower surface of the first overcoat layer, and
wherein the plurality of bridge electrodes is disposed on a lower surface of the touch interlayer insulating layer.

4. The display device according to claim 3, further comprising:
a plurality of touch routing lines disposed in the second non-display area of the second substrate, the plurality of touch routing lines electrically connecting the plurality of touch electrodes and the plurality of second pads,
wherein the plurality of touch routing lines includes:
a first layer disposed on a same layer as the plurality of touch electrodes; and
a second layer disposed on a same layer as the plurality of bridge electrodes and electrically connected to the first layer.

5. The display device according to claim 4, wherein an end of the second flexible film is electrically connected to the plurality of second pads, and wherein a portion of the end of the second flexible film is disposed on a lower side of the second overcoat layer.

6. The display device according to claim 4, wherein the plurality of second pads extends from one end portion of the second layer of the plurality of touch routing lines.

7. The display device according to claim 3, further comprising:
a plurality of color filters disposed on a lower surface of the passivation layer under the second substrate,
wherein the plurality of color filters is disposed to overlap emission areas of the plurality of sub pixels.

8. The display device according to claim 3, further comprising:
a plurality of color filters disposed on a same layer as the black matrix under the second substrate,
wherein plurality of color filters is disposed to overlap emission areas of the plurality of sub pixels.

9. The display device according to claim 3, wherein the black matrix is disposed at the second side portion of the second substrate up to a position spaced inward from an outermost portion of the second substrate by a predetermined distance.

10. The display device according to claim 2, wherein the second non-display area at the second side portion of the second substrate protrudes more than an outermost periphery of the first substrate.

11. The display device according to claim 2, wherein the first non-display area at the first side portion of the first substrate protrudes more than an outermost periphery of the second substrate.

12. The display device according to claim 11, further comprising:
a blocking layer disposed in the first display area on an upper portion of the first substrate;
a thin film transistor disposed on the blocking layer in the first display area of the first substrate, the thin film transistor including an active layer, a gate electrode, a source electrode, and a drain electrode;
a plurality of signal link lines disposed in the first non-display area on the first side portion of the first substrate, the plurality of signal link lines electrically connecting the plurality of sub pixels and the plurality of first pads; and
a light emitting element including a first electrode disposed on the thin film transistor, an emission layer disposed on the first electrode, and a second electrode disposed on the emission layer,
wherein the plurality of first pads is disposed on a same layer as one of the gate electrode, the source electrode, and the drain electrode,
wherein the plurality of first pads includes a same material as one of the gate electrode, the source electrode, and the drain electrode, and
wherein the plurality of signal link lines is disposed on a same layer as the blocking layer and includes a same material as the blocking layer.

13. The display device of claim 3, further comprising:
a thin film transistor disposed in the first display area above the first substrate, the thin film transistor including an active layer, a gate electrode, a source electrode, and a drain electrode, the thin film transistor electrically connected to the light emitting element;
a planarization layer disposed on the thin film transistor;
a bank which is disposed on the planarization layer, the bank having an open portion corresponding to the emission area;
a filling layer disposed between the first substrate and the second substrate at least in the first display area and the second display area;
a dam disposed to surround an outer surface of the filling layer between the first substrate and the second substrate; and
at least one blocking structure disposed in the first non-display area of the first substrate and disposed adjacent to the dam outside the dam,
wherein the at least one blocking structure is disposed on a same layer as the bank and is formed of a same material as the bank.

14. A display device, comprising:
a first substrate including a display area in which a plurality of light emitting elements is disposed, and a non-display area outside the display area;
a second substrate which is opposite to the first substrate at an upper portion of the first substrate;
a filling layer disposed between the first substrate and the second substrate;
at least one dam disposed between the first substrate and the second substrate so as to enclose an outer surface of the filling layer to confine the filling layer;
a plurality of first touch electrodes disposed in a first area corresponding to the display area below the second substrate, the plurality of first touch electrodes extending in a first direction;
a plurality of second touch electrodes extending in a second direction intersecting the first direction;
a plurality of bridge electrodes disposed in the first area under the second substrate, the plurality of bridge electrodes disposed on a different layer from the plurality of first touch electrodes and the plurality of second touch electrodes, the plurality of bridge electrodes electrically connected to a portion of the plurality of second touch electrodes;
a plurality of touch routing lines extending from the first area and disposed in a second area at least partially overlapping the non-display area;
a plurality of touch pads extending from the second area and disposed in a third area non-overlapping with the non-display area at a side of the second substrate; and
a second flexible film electrically connected to the plurality of touch pads at a lower portion of the second substrate.

15. The display device of claim 14, wherein the plurality of touch routing lines includes:
a first layer disposed on a same layer as the plurality of first touch electrodes and the plurality of second touch electrodes; and
a second layer disposed on a same layer as the plurality of bridge electrodes, the second layer electrically connected to the first layer,
wherein the plurality of touch pads extends from one end portion of the second layer of the plurality of touch routing lines.

16. The display device of claim 14, further comprising:
a plurality of color filters disposed below the second substrate and disposed to overlap emission areas of the plurality of light emitting elements; and
a black matrix disposed below the second substrate and disposed not to overlap the emission areas of the plurality of light emitting elements,
wherein at the side of the second substrate, the black matrix is disposed from an outermost portion of the second substrate to a position spaced inwardly by a predetermined distance.

17. The display device according to claim 14, wherein at the side of the second substrate, the third area protrudes more than an outermost periphery of the first substrate.

18. The display device according to claim 14, further comprising:
a plurality of signal pads disposed in the non-display area on a side of the first substrate that does not overlap the side of the second substrate;
a plurality of signal link lines disposed in the non-display area at the side of the first substrate, the plurality of signal link lines electrically connecting the plurality of signal pads and a plurality of sub pixels disposed with the plurality of light emitting elements respectively, of the plurality of light emitting elements; and
a first flexible film electrically connected to the plurality of signal pads at an upper portion of the first substrate.

19. The display device according to claim 18, wherein the non-display area at the side of the first substrate protrudes more than an outermost periphery of the second substrate.

20. The display device according to claim 16, wherein the plurality of color filters is disposed on a same layer as the black matrix.
